(19) United States
(12) Patent Application Publication
(10) Pub. No.: US 2012/0104591 A1
(43) Pub. Date: May 3, 2012

(54) Systems and methods for improved heat dissipation in semiconductor packages

(75) Inventors: Robert W. Warren, Newport Beach, CA (US); Nic Rossi, Causeway Bay (HK)

(73) Assignee: CONEXANT SYSTEMS, INC., NEWPORT BEACH, CA (US)

(21) Appl. No.: 12/925,828

(22) Filed: Oct. 29, 2010

(51) Int. Cl. H01L 23/34; H01L 21/50

(52) U.S. Cl. 257/712; 438/122; 257/E23.08; 257/E21.499

(57) ABSTRACT

Today's high speed semiconductor chips offer high performance at the expense of increase heat generation. A heat spreader can be build into a mold compound covering a semiconductor die in a semiconductor package by forming holes in the mold compound and filling the holes with a thermally conductive material such as thermally conductive adhesive. This heat dissipation capability can further be enhanced by a layer of thermally conductive material on the surface of the mold compound and optionally by an external metal layer or heat sink.

### BACKGROUND OF THE INVENTION

1. Field of the Invention

The invention relates generally to semiconductor packaging and specifically to improving heat dissipation within a semiconductor chip.

2. Background Information

Heat dissipation is essential in semiconductor chips. In the extreme, if a semiconductor chip is allowed to get too hot it can damage the chip. Even outside of this extreme semiconductor chips are designed to operate within a particular temperature range. In order to maintain a chip within its operating temperature range, heat must be drawn away from the chip. As chips become higher performance, they pose a greater challenge as they consume more power and generate more heat.

FIG. 1 illustrates a cross-section of a typical wire bonded, punch singulated package. Fabricated die 102 is attached with die attach 104 to substrate 106. Electrically, fabricated die 102 is accessed through bond wire 108 through bond pad 110. Bond wire 108 is also connected to I/O interfaces on substrate 106. The specific I/O interfaces are dependent on the package type but is typically comprised of one or more layers of metal traces leading to pins or solder balls on the bottom or edge of the substrate.

In high power applications, mold compound 130 can be attached to an external heat sink and in the extreme the heat sink could even be coupled to an electric fan. However, to reach the heat sink, the heat is first drawn through the package material. To this end previous solutions have used more expensive mold compounds for the package material having a higher thermal conductivity. However, in addition to the expense, these mold compounds are less reliable, and are more difficult to use in the transfer molding operation. Another prior solution is the inclusion of internal heat spreader 140 as shown in FIG. 1.

### SUMMARY OF INVENTION

A semiconductor package comprising a substrate with I/O contacts, a semiconductor die having a fabricated pattern and bond pads and attached to the substrate, bond wires electrically coupling the bond pads and the I/O contacts and mold compound covering the semiconductor die. A heat spreader is built into the semiconductor package by forming holes in the top surface of the mold compound in proximity to the die and filling the hole with thermally conductive material. In one embodiment, the thermally conductive material also covers the top surface of the mold compound. Thermally conductive epoxy can be used as the thermally conductive material described above. A metal layer can be attached on top of the package. Such a layer can comprise a metal such as solder, copper, aluminum or some combination of these. Furthermore, a heat sink can be attached on top of the package which can be a finned heat sink or a metal slug, such as a copper or aluminum slug or combination of the two. The heat spreader can be used in both punch singulated and saw singulated packages and the packages can include dual in-line package (DIP) packaging, pin grid array (PGA) packaging, leadless chip carrier (LCC) packaging, small-outline integrated circuit (SOIC) packaging, plastic leaded chip carrier (PLCC) packaging, plastic quad flat pack (PQFP) packaging and thin quad flat pack (TQFP) packaging, thin small-outline packages (TSOP) packaging, land grid array (LGA) packaging and Quad-Flat No-lead (QFN) packaging.

A corresponding method comprises attaching the die to a substrate having I/O contacts, attaching bond wires to bond pads and I/O contacts, covering the die in mold compound, forming holes in the mold compound, depositing thermally conductive material into the holes in the mold compound, and singulating individual packages. The method can further comprise depositing a layer of thermally conductive material on the top surface of the mold compound and/or depositing a layer of metal on the top surface of the mold compound. A metal slug or heat sink such as described above can also be attached.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 illustrates a cross-section of a conventional wire bonded, punch singulated package;

FIG. 2 shows an embodiment of a saw singulated semiconductor package with an externally added heat spreader;

FIG. 3 shows another embodiment of a saw singulated semiconductor package with an externally added heat spreader;

FIG. 4 is a flow chart illustrating the process for packaging a semiconductor die in accordance with an embodiment of the invention;

FIG. 5 is a flow chart illustrating the process for packaging a semiconductor die in accordance with an alternate embodiment of the invention;

FIG. 6 shows a cross sectional view of an exemplary package array after the dies are attached;

FIG. 7 shows a top view of the exemplary package array after the dies are attached;

FIG. 8 shows a cross sectional view of an exemplary package array after wire bonding;

FIG. 9 shows a cross sectional view of an exemplary package array after encapsulation;

FIG. 10 shows a cross sectional view of an exemplary package array after holes are drilled;

FIG. 11 shows a top view of the exemplary package array after holes are drilled;

FIG. 12 shows a cross sectional view of an exemplary package array after holes are filled;

FIG. 13 shows a cross section view of an exemplary package array after optionally depositing an additional metal layer;

FIG. 14 shows a cross section view of an exemplary package array after singulation;

FIG. 15 shows an embodiment of a punch singulated semiconductor package with an externally added heat spreader; and

FIG. 16 shows another embodiment of a punch singulated semiconductor package with an externally added heat spreader.

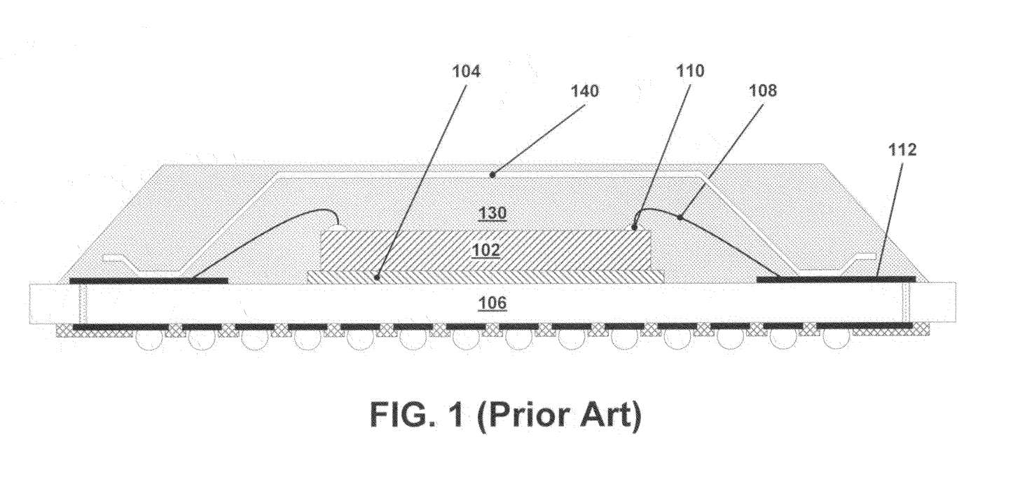

### DETAILED DESCRIPTION

A detailed description of embodiments of the present invention is presented below. While the disclosure will be described in connection with these drawings, there is no intent to limit it to the embodiment or embodiments disclosed herein. On the contrary, the intent is to cover all alternatives, modifications and equivalents included within the spirit and scope of the disclosure as defined by the appended claims.

In modern packaging, semiconductor dies are no longer individually packaged, rather a plurality of packages are arrayed onto a large substrate or metal leadframe, depending on the package type. They are as a group wire bonded, and encapsulated. Additionally other package specific steps may also be performed to the array of dies. Two differences exist between typical punch singulated packaging and saw singulated packaging. First, punch singulated packages typically have individual mold caps so during the encapsulation process each die has essentially a discrete mold whereas in a saw singulated package, the entire array is encapsulated under a single mold. Second, during the singulation process (where the array structure is subdivided into individual packages), a punch is used to knock out each individual package in a punch singulated package, whereas a saw is used to cut out each individual package in a saw singulated package. Because a punch shears away the boundaries between individual packages, it is beneficial that it not have to cut through as much material, hence each die has essentially its own discrete mold cap, whereas a saw can easily cut through substrate and mold compound.

Generally, sawn matrix arrays of semiconductor packages are smaller packages (e.g., having body sizes 4 mm-19 mm) whereas punch singulated packages are larger packages (e.g., 19 mm-43 mm body sizes). In punch singulated packages, a heat spreader can optionally be added after the wire bond process but before the encapsulation process with mold compound. Because of the smaller size of sawn singulated packages and because of the inflexibility of a solid mold encompassing a full package array, attempts at including a heat spreader in saw singulated packages have proven unsuccessful due to warpage incurred during the molding process. In contrast since each die is essentially individually molded in a punch singulated package, a full package array is more flexible and incurs less warpage after the molding process and hence does not encounter as much difficulty in the inclusion of a heat spreader.

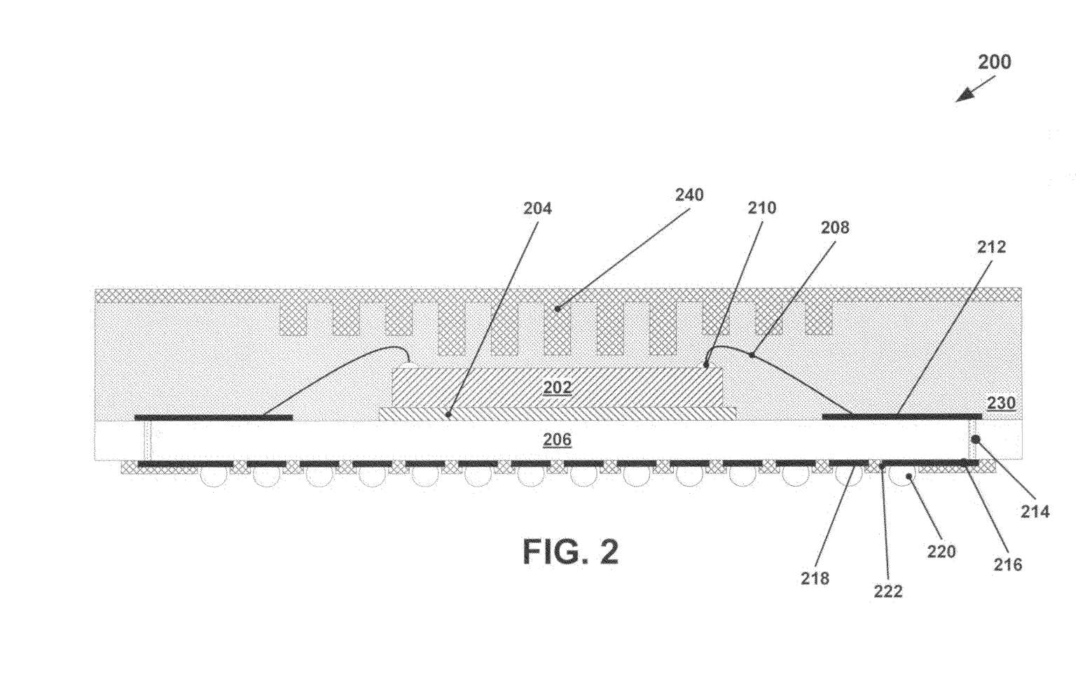

FIG. 2 shows an embodiment of a saw singulated semiconductor package with an externally added heat spreader. Specifically, package 200 is shown as a BGA package. Like in the punch singulated semiconductor package, fabricated die 202 is attached with die attach 204 to substrate 206. Bond wire 208 electrically couples fabricated die 202 through bond pad 210 to metal trace 212. In the BGA example shown, substrate 206 could comprise multiple layers and contain additional metal traces for routing. Metal trace 212 is connected through via 214 to a bond finger such as metal trace 216. Metal traces on the bottom of the substrate such as metal trace 216 comprises a solder pad such as solder pad 218 where a solder ball such as solder ball 220 can be attached at the factory. Solder mask 222 covers the metal traces on the bottom of the substrate but leaves openings exposing the solder pads such as solder pad 218. In one embodiment, mold compound 230 covers fabricated die 202, bond wire 208, and metal trace 212. In another embodiment (not shown), mold compound 230 may cover fabricated die 202 substantially or entirely, but not necessarily bond wire 208 and/or and metal trace 212.

Mold compound 230 has an array of holes formed, such as by laser drilling, into the top surface, the holes are filled and the surface covered with thermally conductive material 240, such as Dupont's CB100 or Epotek H20E thermally conductive materials. Typical thermally conductive epoxies have a thermal conductivity of 3-6 W/m-K. The holes bring thermally conductive material in close proximity to fabricated semiconductor die. In some embodiments, forming holes in areas other than the areas directly above fabricated die 202 is optional. The layer of thermally conductive material can aid in dissipating heat into the environment. A typical thickness for the thermally conductive material can range from 2 to 10 mils.

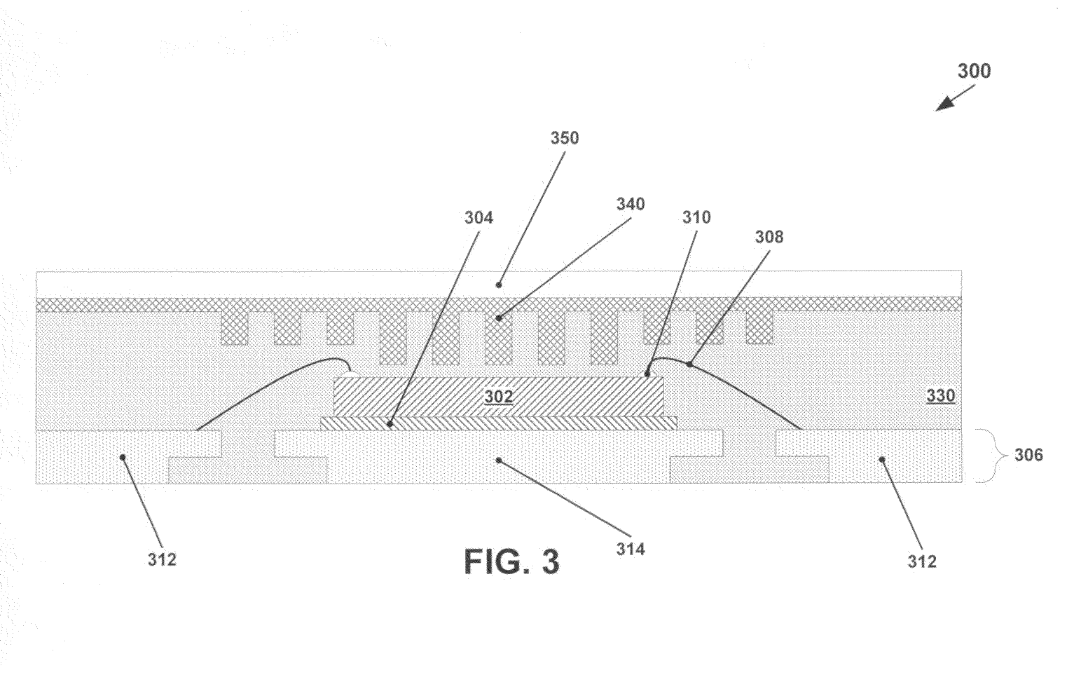

To improve the heat dissipation capability, a metal slug or finned heat sink can be attack to the thermally conductive adhesive. FIG. 3 shows another embodiment of a saw singulated semiconductor package with an externally added heat spreader. Specifically, package 300 is shown as a QFN package. Once again, fabricated die 302 is attached with die attach 304 to substrate 306. In this case, substrate 306 is a metal leadframe comprising I/O pads 312 and thermal pad 314. Bond wire 308 electrically couples fabricated die 302 through bond pad 310 to I/O pad 312. In one embodiment, mold compound 330 covers fabricated die 302, bond wire 308, and I/O pads 312. In another embodiment (not shown), mold compound 330 may cover fabricated die 302 substantially or entirely, but not necessarily bond wire 308 and/or and I/O pads 312. Like in package 200, holes are formed, e.g. by laser drillin, into mold compound 330 and thermally conductive material 340 fills those holes and may also cover the surface of mold compound 330. In some embodiments, forming holes in areas other than the areas directly above fabricated die 302 is optional. In addition, heat sink 350 is attached to the package with thermally conductive material 340. Heat sink 350 can be as simple as a metal slug or can be a finned heat sink. In one embodiment, Heat sink 350 can be a heat sink with a motorized fan.

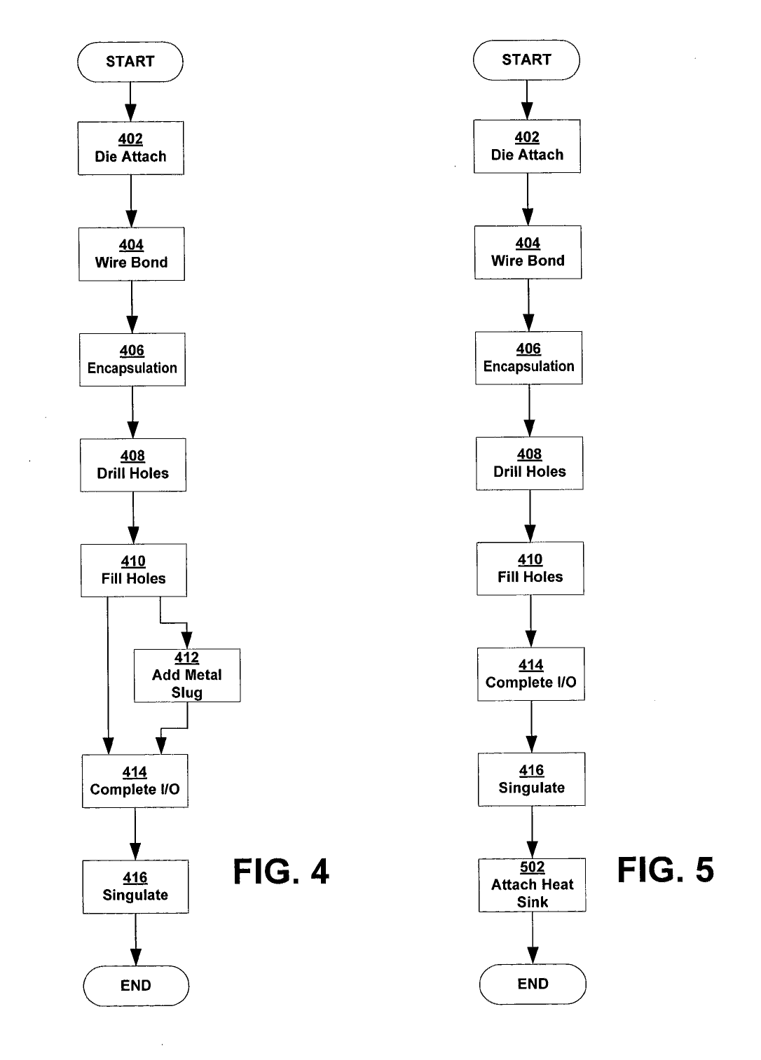

FIG. 4 is a flow chart illustrating the process for packaging a semiconductor die in accordance with an embodiment of the invention. At step 402, an array of fabricated semiconductor dies are attached to a substrate. As mentioned previously, the specific substrate depends on the type of packaging. For example BGA packages often use multiple layered substrates with metal layers to route electrical signals to their respective output interfaces. As another example, QFN packages use a metal leadframe and are not typically multilayered. At step 404, bond pads on each fabricated semiconductor die are wire bonded to I/O contacts on the substrate. Once again the specific type of I/O contact depends on the type of packaging. For example, BGA packages often have metal bond fingers on the surface which lead to vias used to route signals to the external I/O interface, but in QFN packages have an I/O pad which is a single piece of metal. At step 406, each package is encapsulated in mold compound. In the case of a saw singulated package, the entire package array may be encapsulated in a single mold form. In one embodiment, the mold compound may only cover the fabricated die substantially or entirely.

At step 408, an array of holes is formed, such as by drilling, in the mold compound. In one embodiment, the holes are formed over each fabricated semiconductor die. Using a laser to drill the holes utilizes equipment which is already standard in most packaging houses and provide the depth and diameter control desirable at the scale used. Carbon dioxide (CO₂) or yttrium aluminum garnet (YAG) lasers (either Neodymium or Erbium YAG lasers) can be used to drill the holes. A range of hole diameters between 100 and 500 μm can be used. The depth of the holes is dependent on the amount of mold compound above the die, but depths between 50 and 200 μm are typical.

At step 410, the array of holes is filled with thermally conductive material. In addition a layer of thermally conductive material may also be added to cover the surface of the mold compound. Stencil printing is a common way of applying thermally conductive material to the surface of the mold compound.

Optionally at step 412, an additional metal layer can be applied on top of the thermally conductive material. For example, a layer of metal such as copper or solder material could be plated onto the thermally conductive material. Another alternative is to stencil print solder on top of the thermally conductive material. Another option is to apply a metal slug across the entire package array. This added layer of metal improves the thermal dissipation capability of the package.

At step 414, additional steps needed to complete the package are performed. For example, in a BGA solder balls can be attached to the solder pads on the bottom of the substrate. At step 416, the package array is singulated into individual packages. For saw singulated packages, this operation is performed by a saw. For punch singulated packages a punch separates the individual packages.

Depending on the application, it may be desirable to perform steps 414 and 416 in reverse order. For example, in some high end applications, BGA solder balls may be attached after singulation.

FIG. 5 is a flow chart illustrating the process for packaging a semiconductor die in accordance with an alternate embodiment of the invention. Steps 402, 404, 406, 408, 410, 414 and 416 are as described above in FIG. 4. However, rather than the optional step of adding an additional metal layer. At step 502 after singulation, a heat sink of some kind is attached the surface of the mold compound. It can be a metal slug comprising a metal such as copper or aluminum. Whether a metal slug is attached before singulation such as in step 412 in FIG. 4 or after singulation as in step 502 described here depends on a number of factors including the size of the slugs available and the existing equipment available. Alternatively, the heat sink can be a finned heat sink, where the fins add additional surface for heat dissipation. It can even be a heat sink with a motorized fan.

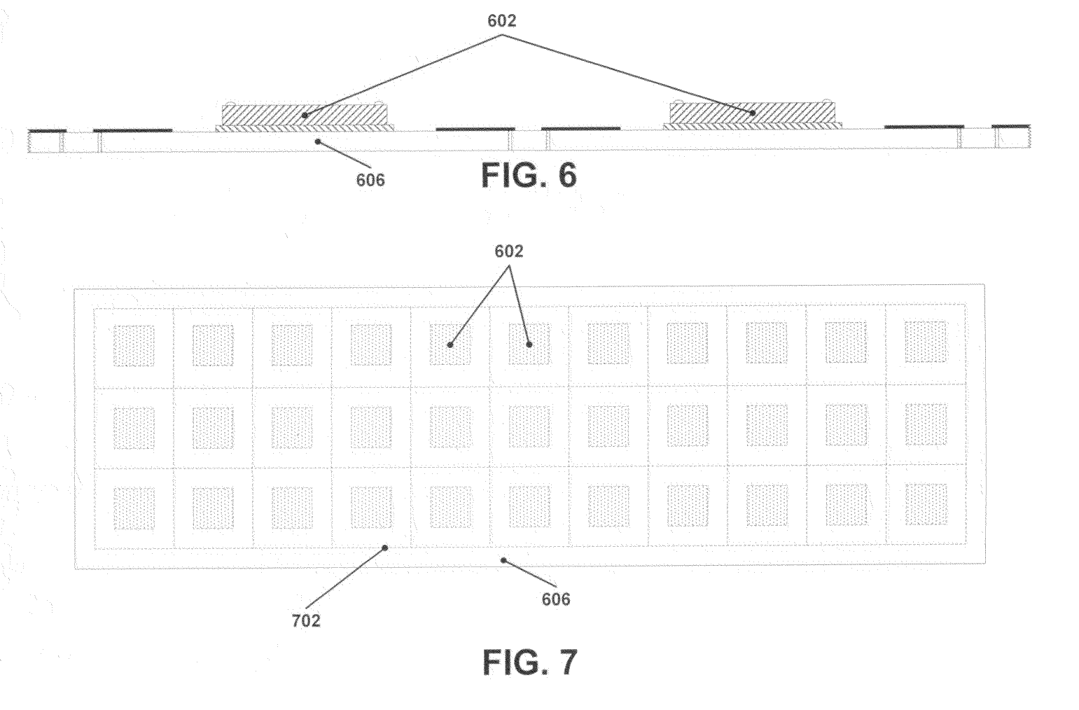

FIGS. 6-14 illustrate the processes described in further detail. FIG. 6 shows a cross sectional view of an exemplary package array after step 402. Semiconductor dies 602 are attached to substrate 606. FIG. 7 shows a top view of the exemplary package array after step 402. In addition to semiconductor dies 602 being attached to substrate 606, dotted lines 702 show the extent of individual packages. They are included for clarity in the diagram and do not necessarily represent any physical markings on the substrate.

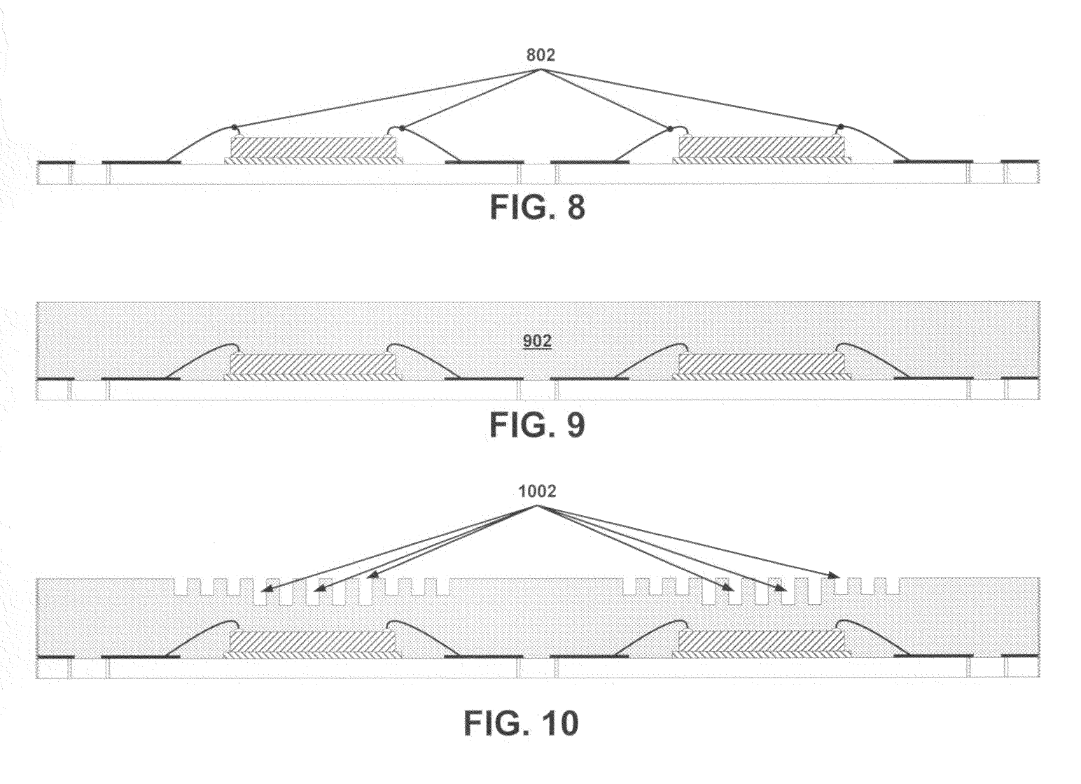

FIG. 8 shows a cross sectional view of an exemplary package array after step 404. Bond wires 802 are used to connect bond pads on each of the fabricated semiconductor dies to their respective I/O contacts on the substrate.

FIG. 9 shows a cross sectional view of an exemplary package array after step 406. The entire package array is encapsulated in mold compound 902. Mold compound 902 extends across multiple packages as shown. As stated above, in some embodiments (not shown), rather than covering the entire package array with mold compound 902, mold compound 902 may only cover the fabricated dies substantially or entirely.

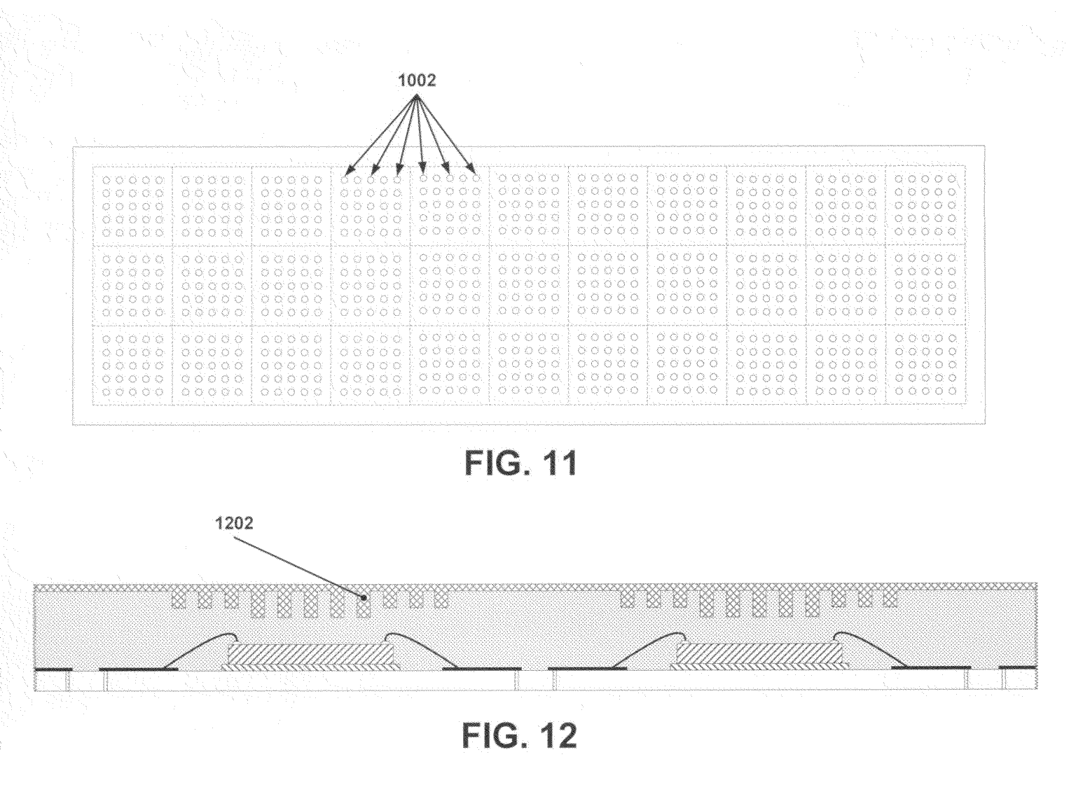

FIG. 10 shows a cross sectional view of an exemplary package array after step 408. Holes such as shown by reference arrows 1002 are formed in the surface of the mold compound as described in greater detail above for step 408. Holes other than the holes directly above the dies are optional in some embodiments. FIG. 11 shows a top view of the exemplary package array after step 408. Once again dotted lines show the extent of each individual package, but do not necessarily represent any actual physical marking.

FIG. 12 shows a cross sectional view of an exemplary package array after step 410. Holes shown in FIGS. 10 and 11 are filled with thermally conductive material 1202 as described above. In addition, the surface of the mold compound is covered with a layer of thermally conductive material typically between 2 and 10 mils in thickness.

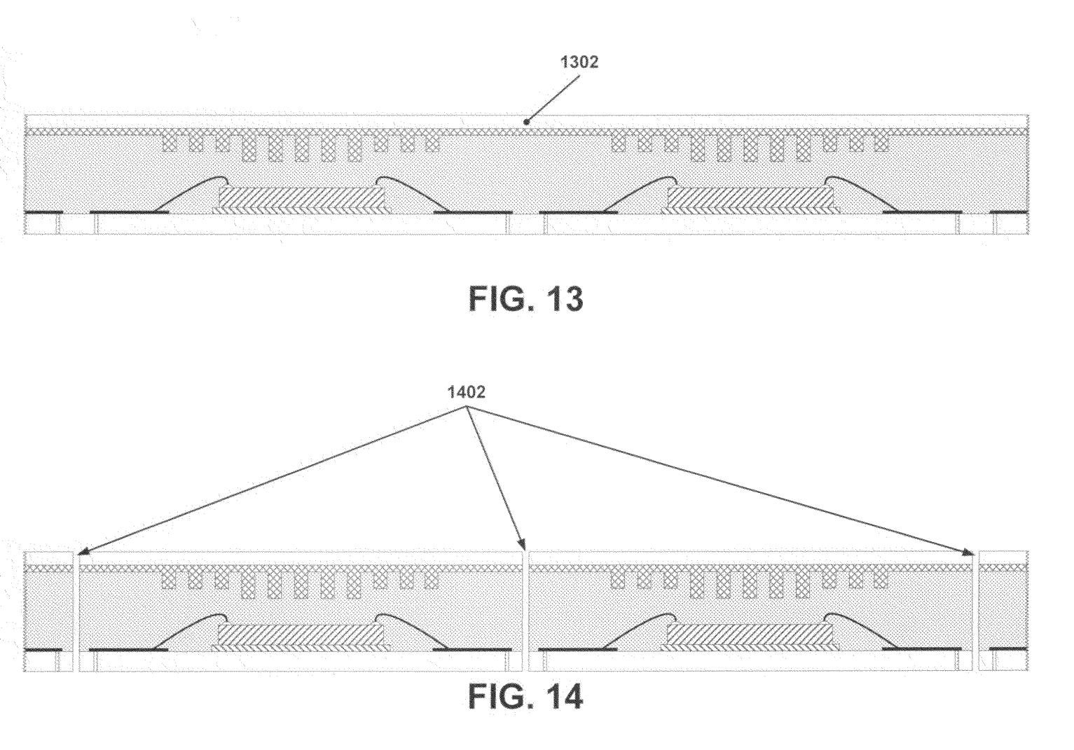

FIG. 13 shows a cross section view of an exemplary package array after optional step 412. Additional metal layer 1302 is added to the top of the thermal conductive layer. This additional metal layer can be a metal slug or metal foil affixed to the thermal conductive layer. Alternatively, it can be a metal layer plated on top of the thermal conductive layer. Still another option is that a solder layer can be printed on top of the thermal conductive layer. Though there are several options described above in FIGS. 4 and 5, depicted in FIG. 13 is the process where additional metal layer 1302 is added before singulation. In the alternative, no additional metal layer 1302 is added or a heat sink is added after singulation.

Finally, FIG. 14 shows a cross section view of an exemplary package array after step 414. At step 414, individual packages are created by singulation. Gaps 1402 represent the kerf of the saw used to singulated the package. Though the disclosure chiefly uses saw singulated packages as an example, individual packages can also be separated by punch singulation.

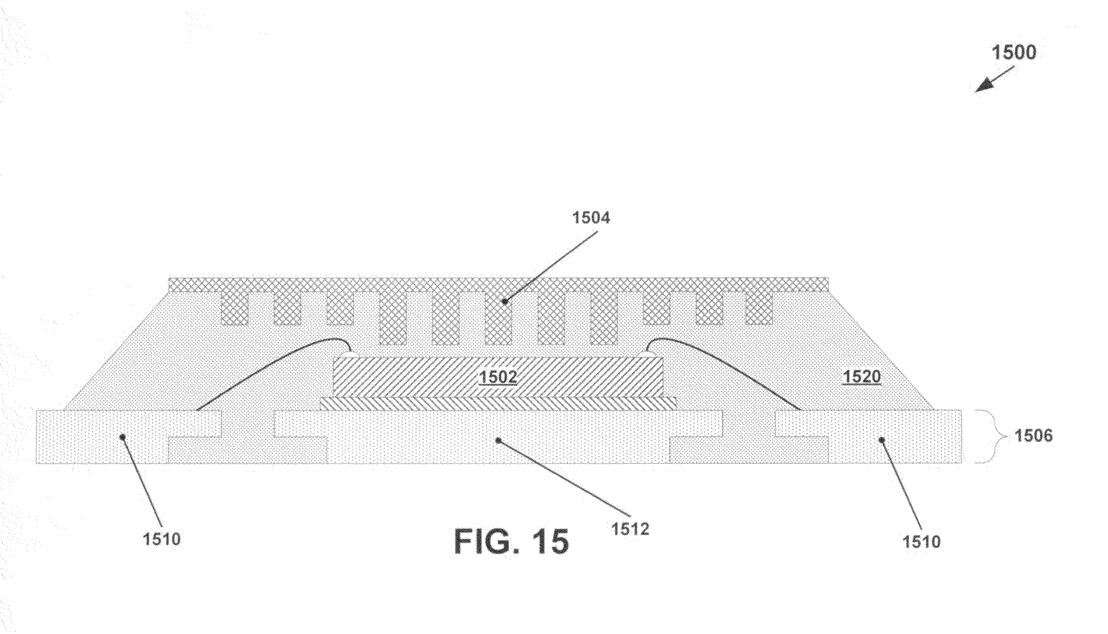

FIG. 15 shows an embodiment of a punch singulated semiconductor package with an externally added heat spreader. In this example, package 1500 is a QFN package comprising fabricated die 1502 attached to metal leadframe 1506 encased in mold compound 1520. Metal leadframe 1506 comprises I/O pads 1510 and thermal pad 1512. Holes are drilled into the top of mold compound 1520 and filled with thermally conductive material 1504. This package can be manufactured using the method described in FIG. 4. Optionally, an additional metal layer or heat sink can be placed on top of the thermally conductive material. This is shown in the following example.

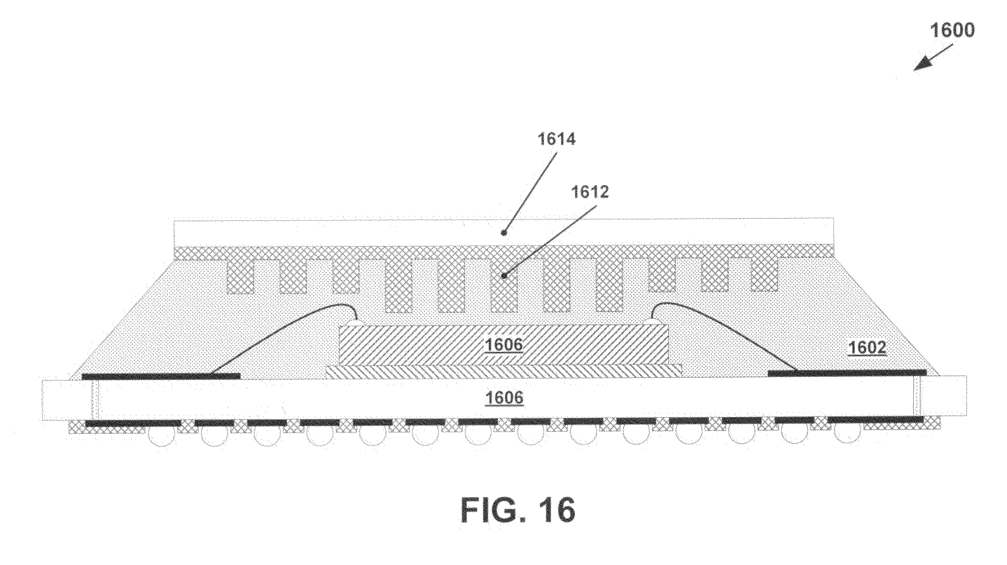

FIG. 16 shows another embodiment of a punch singulated semiconductor package with an externally added heat spreader. In this example, package 1600 is a BGA package comprising fabricated die 1602 attached to substrate 1606 encased in mold compound 1620. Substrate 1606 can comprise several layers and metal traces as described above. Holes are drilled into the top of mold compound 1620 and filled with thermally conductive material 1604. In addition, the heat dissipation is aided by heat sink 1630. This heat sink can simply comprise a metal layer either formed by attaching a metal slug, plating a metal or solder layer, or printing a solder layer. Alternatively, the heat sink can be a finned heat sink or a heat sink with additional cooling mechanisms such as a fan.

In particular the use of the external heat spreading capability of thermally conductive adhesive deposited into holes in the mold compound can be used in many situations where an internal heat spreader is not feasible or not cost efficient.

It should be emphasized that the above-described embodiments are merely examples of possible implementations. Many variations and modifications may be made to the above-described embodiments without departing from the principles of the present disclosure. For example, the above-described embodiments are given for BGA and QFN packaging, but can be applicable to other types of packaging including but not limited to dual in-line package (DIP) packaging, pin grid array (PGA) packaging, leadless chip carrier (LCC) packaging, small-outline integrated circuit (SOIC) packaging, plastic leaded chip carrier (PLCC) packaging, plastic quad flat pack (PQFP) packaging and thin quad flat pack (TQFP) packaging, thin small-outline packages (TSOP) packaging, land grid array (LGA) packaging and Dual-Flat No-lead (DFN) packaging. All such modifications and variations are intended to be included herein within the scope of this disclosure.

What is claimed:

1. A semiconductor package comprising:
a substrate;
a semiconductor die having a fabricated pattern and bond pads, said semiconductor die attached to the substrate;
bond wires attaching the bond pads to the substrate;
a mold compound covering the semiconductor die, said mold compound having a top surface and holes formed in the top surface; and
a thermally conductive material filling the holes in the top surface of the mold compound.

2. The semiconductor package of claim 1 further comprising a layer of thermally conductive material on top of the top surface of the mold compound.

3. The semiconductor package of claim 1 wherein the thermally conductive material comprises a thermally conductive epoxy.

4. The semiconductor package of claim 2 further comprising a layer of metal on top of the layer of thermally conductive material.

5. The semiconductor package of claim 4 wherein the layer of metal comprises solder, copper, aluminum or a combination thereof.

6. The semiconductor package of claim 2 further comprising a heat sink attached on top of the layer of thermally conductive material.

7. The semiconductor package of claim 6 wherein the heat sink is a finned heat sink.

8. The semiconductor package of claim 2 further comprising a metal slug attached on top of the layer of thermally conductive material.

9. The semiconductor package of claim 8 wherein the metal slug comprises copper, aluminum or combination thereof.

10. The semiconductor package of claim 1, wherein the semiconductor package is of a type selected from the group consisting of dual in-line package (DIP) packaging, pin grid array (PGA) packaging, leadless chip carrier (LCC) packaging, small-outline integrated circuit (SOIC) packaging, plastic leaded chip carrier (PLCC) packaging, plastic quad flat pack (PQFP) packaging and thin quad flat pack (TQFP) packaging, thin small-outline packages (TSOP) packaging, land grid array (LGA) packaging and Quad-Flat No-lead (QFN) packaging.

11. A method of packaging a plurality of semiconductor dies each having bond pads comprising:
attaching the plurality of semiconductor dies to a substrate;
attaching bond wires to bond pads on each semiconductor dies and the substrate;
covering the plurality of semiconductor dies
with a mold compound, said covering producing a top surface of the mold compound;
forming holes in the mold compound; and
depositing a thermally conductive material into the holes in the mold compound.

12. The method of claim 11 further comprising:
depositing a layer of thermally conductive material on the top surface of the mold compound.

13. The method of claim 12 further comprising:
depositing a layer of metal on the top surface of the mold compound.

14. The method of claim 13 wherein the metal comprises copper, aluminum, solder or a combination thereof.

15. The method of claim 12 further comprising:
attaching a metal slug on top of the layer of thermally conductive material.

16. The method of claim 15 wherein the metal slug comprises copper, aluminum or a combination thereof.

17. The method of claim 12 further comprising:
attaching a heat sink on top of the layer of thermally conductive material.

18. A method of packaging a semiconductor die having bond pads comprising:
attaching the semiconductor die to a substrate;
attaching bond wires to bond pads on the semiconductor die and the substrate;
covering the semiconductor die with a mold compound, said covering producing a top surface of the mold compound;
forming holes in the mold compound; and
depositing a thermally conductive material into the holes in the mold compound.

19. The method of claim 18 further comprising:
depositing a layer of thermally conductive material on the top surface of the mold compound.

20. The method of claim 19 further comprising
depositing a layer of metal on top of the layer of thermally conductive material.

21. The method of claim 20 wherein the metal comprises copper, aluminum, solder or a combination thereof.

22. The method of claim 19 further comprising
attaching a metal slug on top of the layer of thermally conductive material.

23. The method of claim 22 wherein the metal slug comprises copper, aluminum or a combination thereof.

24. The method of claim 19 further comprising
attaching a heat sink on top of the layer of thermally conductive material.
